(19) United States
(12) Patent Application Publication
(10) Pub. No.: US 2022/0344880 A1
(43) Pub. Date: Oct. 27, 2022

(54) CONNECTION COMPONENT AND CONNECTION UNIT

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventors: Yuta HOSOYA, Yokkaichi-shi (JP); Toshiya HIROOKA, Yokkaichi-shi (JP); Daisuke HASHIMOTO, Yokkaichi-shi (JP); Ayumu ISHIHARA, Yokkaichi-shi (JP); Yoshitomo TSUJII, Yokkaichi-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 17/763,250

(22) PCT Filed: Aug. 28, 2020
(86) PCT No.: PCT/JP2020/032713

§ 371 Date: Mar. 24, 2022

(30) Foreign Application Priority Data
Oct. 9, 2019 (JP) 2019-185881
Feb. 14, 2020 (JP) 2020-023526

(51) Int. Cl. H01R 13/74; H01R 13/52; H01R 13/631; H05K 5/06; F16J 15/10

(52) U.S. Cl. CPC H01R 13/74; H01R 13/52; H01R 13/631; H05K 5/061; F16J 15/10

(57) ABSTRACT

A connection component including: a main body to be attached to a case; and an annular ring that is elastic and into which the main body is inserted, wherein the annular ring deforms between a first thickness at which the annular ring is in contact with the main body and is not in contact with the case when a compressive force that acts in an insertion direction into the case does not occur, and a second thickness at which the annular ring is in contact with both the main body and the case when the compressive force that acts in the insertion direction into the case occurs.

### BACKGROUND

The present disclosure relates to a connection component and a connection unit.

Conventionally, some connection components such as terminal blocks are provided with an elastic member to act as a seal for suppressing ingress of water into an external device to which the connection component is to be attached (see JP 2014-232601A, for example).

A connection component disclosed in JP 2014-232601A is inserted into a mounting hole in a case of an external device, and an elastic member attached to an elastic component attachment portion of the connection component elastically deforms in a radial direction between the elastic component attachment portion and the mounting hole, and thus ingress of water and the like between the mounting hole and the connection component can be suppressed.

### SUMMARY

Incidentally, in the terminal block as described above, since the elastic member interferes with the mounting hole when inserted into the mounting hole, there is a problem in that attachment is difficult. Also, as connection components, some connectors are also provided with an elastic member to perform sealing. Similarly, since the elastic member interferes with the mounting hole when inserted into the mounting hole, there is a problem in that attachment is difficult.

An exemplary aspect of the disclosure provides a connection component that is to be attached to a case and can be easily attached to the case while ensuring sealability between the connection component and the case, and a connection unit provided with the connection component.

A connection component according to the present disclosure includes a main body to be attached to a case; and an annular ring that is elastic and into which the main body is inserted, wherein the annular ring deforms between a first thickness at which the annular ring is in contact with the main body and is not in contact with the case when a compressive force that acts in an insertion direction into the case does not occur, and a second thickness at which the annular ring is in contact with both the main body and the case when the compressive force that acts in the insertion direction into the case occurs.

A connection unit according to the present disclosure is a connection unit including a case, and a connection component including a main body that is attached to the case and an annular ring that is elastic and into which the main body is inserted, wherein the annular ring deforms between a first thickness at which the annular ring is in contact with the main body and is not in contact with the case when a compressive force that acts in an insertion direction into the case does not occur, and a second thickness at which the annular ring is in contact with both the main body and the case when the compressive force that acts in the insertion direction into the case occurs.

According to the present disclosure, a connection component that can be easily attached to a case while ensuring the sealability between the connection component and the case, and a connection unit provided with the connection component can be provided.

### BRIEF DESCRIPTION OF THE DRAWINGS

FIG. 1 is a schematic partial cross-sectional view of a connection unit according to an embodiment.

FIG. 2 is a schematic partial cross-sectional view of the connection unit according to the embodiment.

FIG. 3 is a schematic partial enlarged cross-sectional view of a terminal block according to the embodiment.

FIG. 4 is a schematic partial cross-sectional view of a connection unit according to a variation.

FIG. 5 is a schematic partial cross-sectional view of the connection unit according to the variation.

FIG. 6 is a schematic partial enlarged cross-sectional view of a terminal block according to the variation.

FIG. 7 is a schematic partial enlarged cross-sectional view of the connection unit according to the variation.

### DETAILED DESCRIPTION OF EMBODIMENTS

### Description of Embodiments of Disclosure

First, embodiments of the present disclosure will be listed and illustrated.

A connection component according to the present disclosure is:

[1] a connection component including a main body portion to be attached to a case, and an annular elastic member into which the main body portion is inserted, and the elastic member deforms between a first thickness at which the elastic member is in contact with the main body portion and is not in contact with the case when a compressive force that acts in an insertion direction into the case does not occur, and a second thickness at which the elastic member is in contact with both the main body portion and the case when the compressive force that acts in the insertion direction into the case occurs.

According to this configuration, since the elastic member that deforms between the first thickness and the second thickness is provided, the elastic member is not in contact with the case when in the first thickness, and thus the occurrence of a compressive force between the main body portion and the case due to the elastic member is suppressed when the elastic member is attached to the case. Accordingly, the connection component can be easily attached to the case. Also, when a compressive force that acts in the insertion direction into the case occurs, the elastic member is in contacts with both the main body portion and the case, and thus the sealability between the connection component and the case can be ensured.

[2] It is preferable that the elastic member includes an engaging portion that engages with the main body portion in the insertion direction.

With this configuration, the engaging portion that engages with the main body portion in the insertion direction is provided, and thus the elastic member can be inhibited from coming off the main body portion.

[3] It is preferable that the main body portion includes at least one of a recessed portion and a protruding portion, and the engaging portion has a fitting shape that fits in the at least one of the recessed portion and the protruding portion provided in the main body portion.

With this configuration, the engaging portion has a shape that can fit with at least one of the protruding portion and the recessed portion that are provided in the main body portion, and thus the elastic member can be inhibited from coming off the main body portion.

[4] It is preferable that the engaging portion is a fitting protrusion that fits in the recessed portion of the main body portion, and the fitting protrusion is provided at an intermediate position of the elastic member in the insertion direction.

With this configuration, the fitting protrusion provided in the intermediate position in the insertion direction fits into the recessed portion of the main body portion, and thus the elastic member can be inhibited from coming off the main body portion.

[5] It is preferable that the fitting protrusion includes an abutting portion that abuts against the recessed portion when the compressive force occurs on an upstream side in the insertion direction.

With this configuration, when a compressive force that acts in the insertion direction occurs, the abutting portion of the fitting protrusion abuts against the recessed portion, and thus the fitting protrusion can be readily deformed in a direction intersecting the insertion direction. For this reason, when a compressive force that acts in the insertion direction into the case occurs, the elastic member including the fitting protrusion is deformed in a direction intersecting the insertion direction, and thus sealability can be ensured.

[6] It is preferable that the fitting protrusion includes a downstream side engaging portion configured to engage with the recessed portion on a downstream side in the insertion direction.

With this configuration, the fitting protrusion includes the downstream side engaging portion that can engage with the recessed portion on the downstream side in the insertion direction, and thus the elastic member can be inhibited from coming off the main body portion.

[7] It is preferable that the fitting protrusion includes a chamfered portion that is formed in a curved shape at a corner portion of a base end.

With this configuration, since the fitting protrusion includes the chamfered portion formed in a curved shape at the corner portion of the base end, concentration of the stress on the corner portion can be suppressed when the compressive force acts on the fitting protrusion. In this manner, the compressive force can be made to act on the entirety of the fitting protrusion, and the fitting protrusion can be readily deformed in a direction intersecting the insertion direction. As a result, when the compressive force that acts in the insertion direction into the case occurs, the elastic member including the fitting protrusion is deformed in a direction intersecting the insertion direction, enabling sealability to be ensured.

[8] It is preferable that the elastic member includes an outer circumferential surface that bulges outwards.

With this configuration, when the compressive force that acts in the insertion direction occurs and the elastic member deforms in a direction intersecting the insertion direction, the bulging outer circumferential surface can be easily and actively brought into contact with the case, and thus it can contribute to improve the sealability.

[9] It is preferable that the elastic member includes a tapered lip portion at both end portions on the upstream and downstream sides in the insertion direction.

With this configuration, since the tapered lip portions are respectively provided at the end portion on the upstream side in the insertion direction and at the end portion on the downstream side in the insertion direction, when a force in the compressive direction acts on the lip portions, the contact areas of the lip portions are small, and thus the elastic member can be deformed in a direction intersecting the insertion direction with a small force.

Further, a connection unit according to the present disclosure is [10] a connection unit including a case, and a connection component including a main body portion that is attached to the case and an annular elastic member into which the main body portion is inserted, and the elastic member deforms between a first thickness at which the elastic member is in contact with the main body portion and is not in contact with the case when a compressive force that acts in an insertion direction into the case does not occur, and a second thickness at which the elastic member is in contact with both the main body portion and the case when the compressive force that acts in the insertion direction into the case occurs.

With this configuration, since the elastic member that deforms between the first thickness and the second thickness is provided, in the case of the first thickness, the elastic member is not in contact with the case, and thus occurrence of a pressing force between the main body portion and the case due to the elastic member can be suppressed when the elastic member is attached to the case. In this manner, the connection component can be easily attached to the case. Also, when the compressive force that acts in the insertion direction into the case occurs, the elastic member comes into contact with both the main body portion and the case, enabling the sealability between the connection component and the case to be ensured.

[11] It is preferable that the case includes a housing portion that houses the elastic member and is in contact with the elastic member in a direction that intersects the insertion direction when the elastic member is the second thickness.

With this configuration, due to the housing portion that comes into contact with the elastic member in a direction intersecting the insertion direction when the elastic member is the second thickness, the elastic member can be inhibited from further moving and deforming in a direction intersecting the insertion direction, and intimate contact between the housing portion and the elastic member and between the elastic member and the main body portion can be maintained.

[12] It is preferable that one of the case and the connection component includes a guide pin, and the other of the case and the connection component includes an insertion hole for inserting the guide pin.

With this configuration, the connection component can be guided and positioned with respect to the case with the guide pin and the insertion hole, enabling attachment to be facilitated.

[13] It is preferable that the main body portion includes a lid portion that closes an opening portion of the case and an insertion portion to be inserted into the opening portion.

With this configuration, due to the lid portion that closes the opening portion of the case, ingress of water and the like through the opening portion can be suppressed.

[14] It is preferable that a leading end portion of the insertion portion has a tapered shape that is tapered toward a leading end side.

With this configuration, due to the leading end portion of the insertion portion being tapered toward the leading end, the insertion portion can be guided when being inserted into the opening portion of the case, enabling attachment to be facilitated.

[15] It is preferable that the connection unit includes a holding member that holds the elastic member of the connection component in the case in a state where the elastic member is the second thickness.

With this configuration, due to the elastic member being held in the case in the second thickness by the holding member, sealability can be ensured.

[16] It is preferable that the holding member is a thread fastening member.

With this configuration, due to the thread fastening member being adopted as the holding member, the elastic member can be held in the second thickness by the fastening force applied by the thread fastening member.

### Description of Embodiments of Disclosure

Specific examples of the connection component and the connection unit according to the present disclosure will be described with reference to the drawings. Note that in the drawings, parts of the configuration may be shown in an exaggerated or simplified manner for convenience of description. Moreover, in the drawings, dimensional ratios of various portions may be different from actual dimensional ratios. “Parallel” and “orthogonal” in the present specification encompass being generally parallel and orthogonal in a range that achieves the operations and effects of the present embodiment, in addition to being strictly parallel and orthogonal. Note that the present disclosure is not limited to these illustrative examples and is defined by the claims, and all changes which come within the meaning and range of equivalency of the claims are intended to be embraced therein.

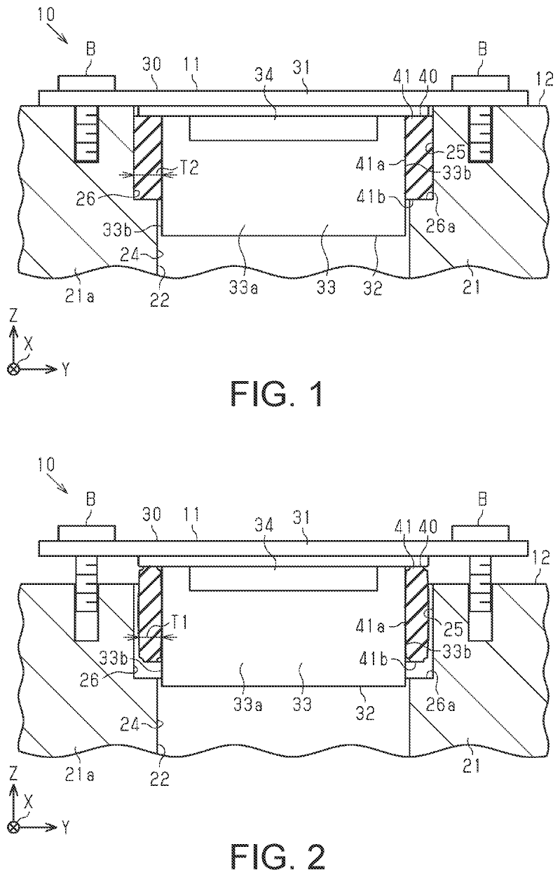

As shown in FIG. 1, a connection unit 10 includes a terminal block 11 and a case 12 to which the terminal block 11 is attached.

The case 12 includes a box-like case main body 21 and a mounting hole 22 provided in the case main body 21, for example. The case 12 is used as a motor case for housing a motor or an inverter case for housing an inverter, for example. A metal material such as iron or aluminum can be used as a material for the case 12, for example. The case 12 may be subjected to surface finishing such as tinning or aluminum plating according to the type of constituent metal and the usage environment thereof.

The mounting hole 22 passes through the wall portion 21a of the case main body 21 such that the inner space of the case main body 21 and the outer space of the case main body 21 communicate with each other. The mounting hole 22 is formed in a flat shape that has a longitudinal direction and a short direction as seen in the through direction. In the present specification, “flat shape” encompasses an oval shape and an ellipse shape, for example. Note that “oval shape” in the present specification means a shape formed by two parallel lines that substantially have the same length and two semicircles. The mounting hole 22 in the present embodiment is formed in an oval shape as seen in the through direction.

The mounting hole 22 may be formed as a so-called stepped hole. As shown in FIGS. 1 and 2, the mounting hole 22 includes a first mounting hole 24 and a second mounting hole 25. The first mounting hole 24 and the second mounting hole 25 are arranged side by side in the through direction. The first mounting hole 24 is located on the inner space side in the through direction of the case main body 21 relative to the second mounting hole 25. The second mounting hole 25 is located on the outer space side in the through direction of the case main body 21 relative to the first mounting hole 24.

The first mounting hole 24 and the second mounting hole 25 are formed in a flat shape that has a longitudinal direction and a short direction as seen in the through direction as described above. The longitudinal direction of the first mounting hole 24 substantially matches the longitudinal direction of the second mounting hole 25. The short direction of the first mounting hole 24 substantially matches the short direction of the second mounting hole 25.

The length in the longitudinal direction of the second mounting hole 25 is longer than the length in the longitudinal direction of the first mounting hole 24. The length in the short direction of the second mounting hole 25 is longer than the length in the short direction of the first mounting hole 24. In this manner, the second mounting hole 25 is a through hole formed by enlarging the first mounting hole 24, and is an opening that is larger than the first mounting hole 24 in the entirety in circumferential direction. As a result, a stepped portion is formed between the first mounting hole 24 and the second mounting hole 25.

The second mounting hole 25 includes the housing portion 26 (housing). The housing portion 26 shows the entirety of the space of the portion by which the second mounting hole 25 enlarges from the first mounting hole 24. In other words, the housing portion 26 is an oval annular portion on the outside in the radial direction in the second mounting hole 25. The housing portion 26 includes a bottom portion 26a formed by the stepped portion between the first mounting hole 24 and the second mounting hole 25.

Next, the structure of the terminal block 11 will be described. The terminal block 11 can be attached into the mounting hole 22 of the case 12, and in the following description, the through direction of the mounting hole 22 is referred to as a height direction regardless of the position of the mounting hole 22 of the case 12 and the orientation of the mounting hole 22 in the through direction.

Note that, in the drawings, the X axis of the XYZ axes indicates the front-rear direction of the terminal block 11, the Y axis indicates the width direction of the terminal block 11 that is orthogonal to the X axis, and the Z axis indicates the height direction of the terminal block 11 that is orthogonal to the XY plane. In the following description, for illustrative reasons, the direction extending along the X axis is referred to as the front-rear direction X, the direction extending along the Y axis is referred to as the width direction Y, and the direction extending along the Z axis is referred to as the height direction Z. In the following description, the Z arrow direction in FIG. 1 is upward, and the opposite direction is downward.

### Configuration of Terminal Block 11

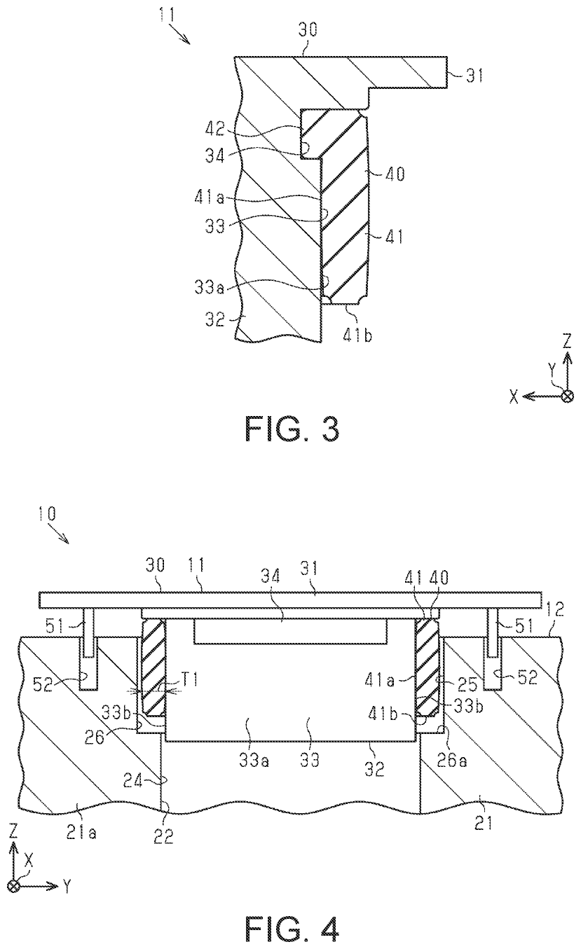

As shown in FIGS. 1 to 3, the terminal block 11 includes a main body portion 30 (main body) and an elastic member 40 (annular ring) attached to the main body portion 30.

### Configuration of Main Body Portion 30

As shown in FIGS. 1 and 2, the main body portion 30 includes a lid portion (lid) 31 and the insertion portion 32 (insertion body). The main body potion 30 is a housing made of a synthetic resin, for example. The main body portion 30 is configured to hold a terminal (not shown). One or plurality of terminals may be held by the main body portion 30. The main body portion 30 is configured to be fixed to the case 12 with a bolt B that serves as a thread fastening member.

The outline and projection area of the lid portion 31 is larger than that of the mounting hole 22 as seen in the height direction Z. As shown in FIG. 1, the lid portion 31 is configured to close the mounting hole 22 in the state where the terminal block 11 is mounted in the mounting hole 22. The lid portion 31 is formed in an oval plate, for example.

The insertion portion 32 is to be inserted into the mounting hole 22. The outer circumferential surface 33 of the insertion portion 32 is formed in a shape that conforms to the inner circumferential surface of the mounting hole 22. In other words, the insertion portion 32 is formed in a flat shape that has a longitudinal direction and a short direction as seen in the height direction Z. In the present embodiment, the outer circumferential surface 33 of the insertion portion 32 includes two flat surface portions 33a that substantially have the same length and two curved surface portions 33b that respectively link the end portions of the flat surface portions 33a. The insertion portion 32 is inserted into the first mounting hole 24 and the second mounting hole 25 so as to straddle the two holes.

The outer circumferential surface 33 of the insertion unit 32 includes a recessed portion 34 (recess) that is recessed inward in the radial direction. The recessed portion 34 is provided in the upper end portion in the height direction Z of the insertion portion 32. In the present embodiment, the recessed portion 34 is provided in the flat surface portion 33a of the outer circumferential surface 33, for example. Note that, the position of the recessed portion 34 may be changed as appropriate. Specifically, the recessed portions 34 may be respectively provided in both the flat surface portion 33a and the curved surface portion 33b, or the recessed portion 34 may be provided only in the curved surface portion 33b. When the recessed portions 34 are provided in both the flat surface portion 33a and the curved surface portion 33b, for example, the plurality of recessed portions 34 may be provided continuously around the entirety of the outer circumferential surface 33 in the circumferential direction, or may be provided at intervals in the circumferential direction.

An elastic member 40 is attached to the outer circumferential surface 33 of the insertion unit 32.

### Configuration of Elastic Member 40

The elastic member 40 is configured to be elastically deformable. The elastic member 40 includes an annular portion 41 and a protruding portion 42 (protrusion) that protrudes from the inner circumferential surface 41a of the annular portion 41.

The annular portion 41 is formed in a closed ring that is continuous around the entirety of the insertion portion 32 in the circumferential direction. The inner circumferential shape of the annular portion 41 is formed in a shape that conforms to the outer circumferential surface of the insertion portion 32, for example. The outer circumferential shape of the annular portion 41 is formed in a shape that conforms to the inner circumferential surface of the mounting hole 22, for example.

The annular portion 41 of the present embodiment is formed in an elongated cylindrical shape in which the inner circumference and the outer circumference are formed in an oval shape. The annular portion 41 has a greater outer diameter than the outer diameter of the first mounting hole 24 in the state in which the annular portion 41 is attached to the insertion portion 32.

The protruding portion 42 is formed in the position corresponding to the recessed portion 34 of the flat surface portion 33a of the annular portion 41, for example. The protruding portion 42 is fitted into the recessed portion 34. Since the protruding portion 42 is fitted into the recessed portion 34, the elastic member 40 can be positioned with respect to the main body portion 30 in the circumferential direction and the elastic member 40 can be inhibited from coming off the main body portion 30.

The elastic member 40 is constituted of rubber. Acrylic rubber can be used as an example of the rubber material for the elastic member 40. Since acrylic rubber is adopted as the elastic member 40, the seal member that is excellent in heat-resistance and an oil resistance can be achieved. Note that the rubber material for the elastic member 40 may also be a material other than acrylic rubber, and if a material such as silicone rubber, fluorine-contained rubber, or hydrogenated nitrile rubber is adopted, the seal member that is excellent in heat-resistance and oil-resistance can be achieved. Also, the rubber material for the elastic member 40 may also be a synthetic rubber member such as ethylene-propylene rubber (EPDM) or a natural rubber material.

Since the elastic member 40 is constituted of rubber, the volume of the elastic member 40 hardly changes before and after elastic deformation. For example, by the elastic member 40 being compressed in the compression direction, the elastic member 40 can be expanded in a direction that is different from the compression direction, such as, for example, a direction orthogonal to the compression direction.

For example, the thickness of the elastic member 40 after the elastic member 40 is compressed in the insertion direction by bringing the lower end surface 41b of the annular portion 41 into contact with the bottom portion 26a of the housing portion 26 is different from the thickness of the elastic member 40 before bringing the lower end surface 41b of the annular portion 41 into contact with the bottom portion 26a of the housing portion 26. The thickness of the elastic member 40 indicates the wall thickness of the annular portion 41, that is the distance between the outer circumferential surface and the inner circumferential surface of the annular portion 41. In the present embodiment, as shown in FIG. 2, before the lower end surface 41b of the annular portion 41 is brought into contact with the bottom portion 26a of the housing portion 26, the thickness of the elastic member 40 is relatively a first thickness T1. Also, as shown in FIG. 1, after the elastic member 40 is compressed in the insertion direction by bringing the lower end surface 41b of the annular portion 41 into contact with the bottom portion 26a of the housing portion 26, the thickness of the elastic member 40 is a second thickness T2 that is thicker than the first thickness T1. In other words, the elastic member 40 of the present embodiment deforms between the first thickness T1 and the second thickness T2. Note that the second thickness T2 of the elastic member 40 shown in FIG. 1 is the thickness in the state in which fastening of the main body portion 30 to the case 12 with the bolt B is completed, in other words, in the state where the fixing of the main body portion 30 to the case 12 is completed. The outer diameter of the elastic member 40 in the first thickness T1 is smaller than the inner diameter of the second mounting hole 25. The outer diameter of the elastic member 40 in the second thickness T2 is the same as the inner diameter of the second mounting hole 25.

The operations of the present embodiment will be described below.

In the connection unit 10 of the present embodiment, the terminal block 11 is fixed by being fastened to the case 12 with the bolt B. At this time, the annular elastic member 40 that is attached to the main body portion 30 of the terminal block 11 is compressed in the height direction Z that is the insertion direction and expands in the width direction Y and the front-rear direction X that are orthogonal to the height direction Z to become the second thickness T2, and comes into contact with both the main body portion 30 and the case 12. On the other hand, when the compressive force that acts in the insertion direction into the case 12 does not occur at the time of attaching the terminal block 11 to the main body portion 30, the elastic member 40 becomes the first thickness T1, and comes into contact with the main body portion 30 and is not in contact with the case 12.

The effects of the present embodiment will be described.

(1) Since the elastic member 40 that deforms between the first thickness T1 and the second thickness T2 are provided, the elastic member 40 is not in contact with the case 12 when the elastic member 40 is the first thickness T1, and thus the occurrence of the pressing force between the main body portion 30, and the case 12 can be suppressed when attaching the elastic member 40 to the case 12. In this manner, the elastic member 40 can be easily attached to the case 12. Further, when the compressive force that acts in the insertion direction into the case 12 occurs, the elastic member 40 comes into contact with both the main body portion 30 and the case 12, and thus sealability between the elastic member 40 and the case 12 can be ensured.

(2) Due to the protruding portion 42 serving as the engaging portion (engagement) that engages with the main body portion 30 in the insertion direction, the elastic member 40 can be inhibited from coming off the main body portion 30.

(3) By the protruding portion 42 that fits into the recessed portion 34 provided in the main body portion 30 as the fitting portion being adopted, the elastic member 40 can be inhibited from coming off the main body portion 30.

(4) Due to the housing portion 26 that comes into contact with the elastic member 40 in the direction intersecting the insertion direction when the elastic member 40 is the second thickness T2, the elastic member 40 can be inhibited from further moving and deforming in a direction intersecting the insertion direction, and intimate contact between the housing portion 26 and the elastic member 40 and between the elastic member 40 and the main body portion 30 can be maintained.

(6) Due to the lid portion 31 that closes the mounting hole 22, which is the opening portion of the case 12, ingress of water through the mounting hole 22 can be suppressed.

(7) Due to the elastic member 40 being held by the case 12 while the elastic member 40 is the second thickness T2, with the bolt B serving as the holding member (holding body), sealability can be ensured.

(8) By the bolt B serving as the thread fastening member being adopted, the elastic member can be held in the second thickness T2 by the fastening force of the bolt B.

### Other Embodiments

The present embodiment can be implemented by modifying as follows. The present embodiment and the modifications below may be implemented in combination with each other as long as no technical contradictions arise.

Although not mentioned in the above embodiment, a configuration can also be adopted in which one of the case 12 and the terminal block 11 includes a guide pin, and the other of the case 12 and the terminal block 11 includes an insertion hole for inserting the guide pin.

As shown in FIG. 4, the guide pin 51 is included in the lid portion 31 of the terminal block 11, and an insertion hole 52 for inserting the guide pin 51 is provided in the case 12. The guide pin 51 has a cylindrical shape. Although the guide pin 51 has a cylindrical shape in the example shown in FIG. 4, there is no limitation to this. For example, the guide pin 51 may also be a tapered shape that is tapered toward the leading end. In this case, for example, it is preferable that the shape of the insertion hole conforms to the shape of guide pin.

By adopting the above configuration, since the terminal block 11 serving as the connection component can be guided and positioned with respect to the case 12 using the guide pin 51 and the insertion hole 52, attachment can be facilitated.

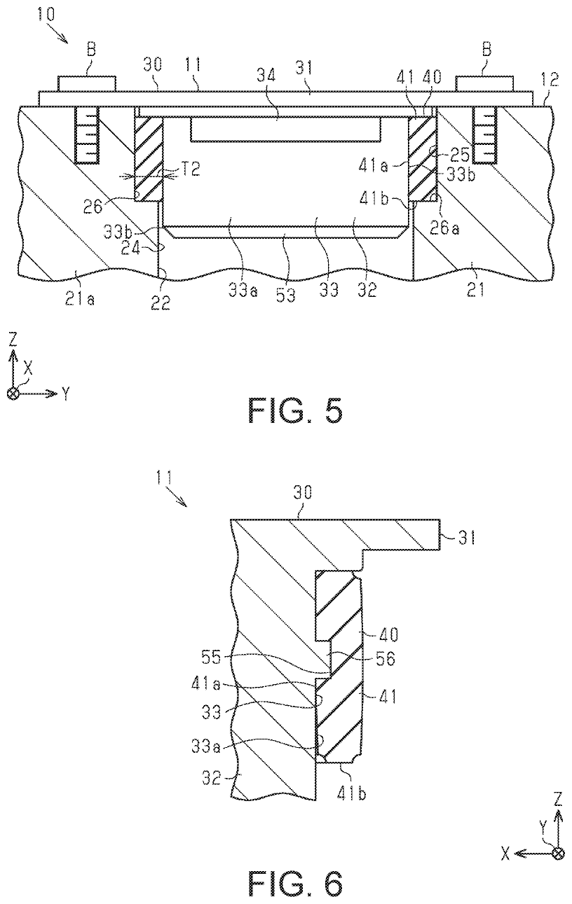

As shown in FIG. 5, the leading end portion 53 of the insertion portion 32 may be tapered toward the leading end. By adopting this configuration, since the insertion portion 32 can be guided when the insertion portion 32 is inserted into the attachment hole 22 of the case 12, attachment can be easily performed.

In the above embodiment, a configuration in which the elastic member 40 includes the protruding portion 42 is adopted, but a configuration in which the protruding portion 42 is omitted may also be adopted. If the protruding portion 42 is omitted, the inner diameter of the elastic member 40 is made smaller than the outer diameter of the main body portion 30, and the elastic member 40 is attached to the main body portion 30 using the elastic force (fastening force) of the elastic member 40.

A configuration may also be adopted in which the elastic member 40 is provided with a recessed portion 55 serving as the engaging portion, and the recessed portion 55 is fitted to the protruding portion 56 of the main body portion 30, as shown in FIG. 6. Further, a configuration is also possible in which the main body portion 30 is provided with both a recessed portion and a protruding portion, and the elastic member 40 is provided with both a protruding portion and a recessed portion as a fitting shape. With this configuration as well, similar to the above embodiment, the elastic member 40 can be inhibited from coming off the main body portion 30.

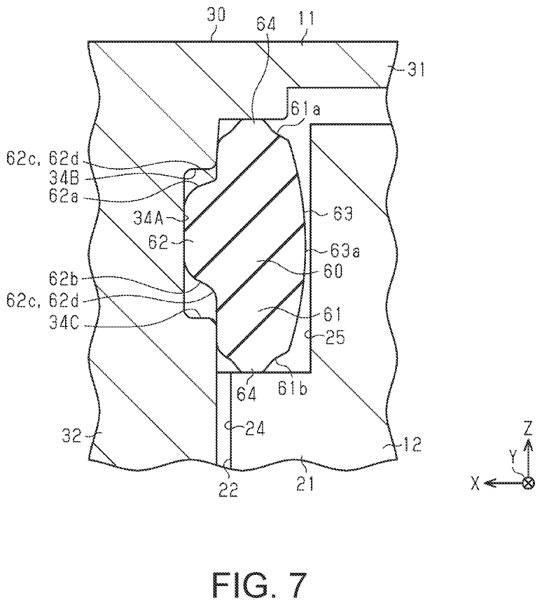

Also, an elastic member 60 as shown in FIG. 7 may also be adopted. The detail of elastic member 60 will be described below. Note that the following configuration of the elastic member 60 can also be adopted with the elastic member 40 of the above embodiment as appropriate.

As shown in FIG. 7, similar to the elastic member 40 of the above embodiment, the elastic member 60 can elastically deform. The same material as the elastic member 40 can be used in the elastic member 60. The elastic member 60 includes an annular portion 61 and a fitting protrusion 62 that protrudes from the inner circumferential surface of the annular portion 61.

Similarly to the annular portion 41, the annular portion 61 is formed in a closed ring-like shape that is continuous around the entirety of the insertion portion 32 in the circumferential direction. The annular portion 61 of the present example is formed in an elongated cylindrical shape in which the inner circumferential shape and the outer circumferential shape are oval. The outer diameter of the annular portion 61 is larger than the outer diameter of the first mounting hole 24 in the state in which the annular portion 61 is attached to the insertion portion 32.

The fitting protrusion 62 is formed in a position corresponding to the recessed portion 34A of the case 12 of the annular portion 61, for example.

The fitting protrusion 62 is formed at an intermediate position in the height direction Z that substantially coincides with the through direction of the annular portion 61. More specifically, the fitting protrusion 62 is formed extending inward from the inner circumferential surface of the annular portion 61 such that the center of the fitting protrusion 62 itself is located slightly above the approximate center in the height direction Z of the annular portion 61. In this manner, by the fitting protrusion 62 provided at the intermediate position in the insertion direction fitting to the recessed portion 34A of the main body portion 30, the elastic member 60 can be inhibited from coming off the main body portion 30.

The length of the fitting protrusion 62 in the height direction Z is shorter than the length of the recessed portion 34A in the height direction Z.

The fitting protrusion 62 includes an abutting portion 62a (abutment) that abuts against an upper wall portion 34B of the recessed portion 34A when the compressive force acts on the upstream side in the insertion direction. In this manner, due to the abutting portion 62a of the fitting protrusion 62 and the upper wall portion 34B of the recessed portion 34A abutting against each other when the compressive force that acts in the insertion direction occurs, the fitting protrusion 62 can be easily deformed in a direction intersecting the insertion direction. As a result, when the compressive force that acts in the insertion direction into the case 12 occurs, the elastic member 60 including the fitting protrusion 62 is deformed in a direction intersecting the insertion direction, enabling sealability to be ensured.

The fitting protrusion 62 is configured such that the lower end portion 62b serving as the downstream side engaging portion (downstream side engagement) can engage with the lower wall portion 34C of the recessed portion 34A on the downstream side in the insertion direction. The lower end 62b of the fitting protrusion 62 is configured to engage with the lower wall portion 34C of the recessed portion 34A on the downstream side in the insertion direction, and thus the elastic member 60 can be inhibited from coming off the main body portion 30.

The fitting protrusion 62 includes a chamfered portion 62d (chamfer) formed in a curved surface at a corner portion 62c of the base end (boundary portion with the annular portion 61). In this manner, since the fitting protrusion 62 includes the chamfered portion 62d formed in a curved surface at the corner portion 62c at the base end, the concentration of stress at the corner portion 62c can be suppressed when the compressive force acts on the fitting protrusion 62. In this manner, since the compressive force can act on the entirety of the fitting protrusion 62, the fitting protrusion 62 can be easily deformed in a direction intersecting the insertion direction (height direction Z). For this reason, when the compressive force that acts in the insertion direction into the case 12 occurs, the elastic member 60 including the fitting protrusion 62 is deformed (expanded) in a direction intersecting the insertion direction and the sealability can be ensured.

The annular portion 61 of the elastic member 60 includes the bulging portion 63a that bulges outward from the outer circumferential surface 63. Specifically, the bulging portion 63a is formed such that the entirety of outer circumferential surface 63 is curved such that the approximate center in the height direction Z of the annular portion 61 bulges most outwardly. In this manner, when the compressive force that acts in the insertion direction (height direction Z) occurs with respect to the elastic member 60, the bulging portion 63a further deforms outward, and thus, the bulged outer circumferential surface 63 (bulging portion 63a) can be easily and positively brought into contact with the case 12. As a result, it can contribute to improvement of the sealability between the case 12 and the elastic member 60.

The annular portion 61 of the elastic member 60 includes lip portions 64 (lips) at both the end portion 61a on the upstream side in the insertion direction and the end portion 6 1b on the downstream side in the insertion direction, respectively. The lip portions 64 have a tapered shape that is tapered toward the leading end side. For this reason, when the force acts on the lip portions 64 in the compression direction, since the contact areas of the lip portions 64 are small, the pressure (force per unit area) acting on the lip portions 64 can be increased. As a result, the elastic member 60 can be easily deformed in a direction intersecting the compression direction, and this contributes to improvement in sealability. Note that, in this example, the lip portions 64 are provided at the end portions 61a and 61b on both sides in the insertion direction, but a configuration may also be adopted in which the lip portion 64 is provided at only one end in the insertion direction.

Although the bolt B is adopted as the thread fastening member in the above embodiment, there is no limitation to this. For example, a configuration may also be adopted in which a stud bolt is provided on the case 12 side, an insertion hole for inserting the stud bolt is provided to the main body portion 30, and fastening is performed with the stud bolt and a nut.

Although the terminal block 11 is adopted as the connection component in the above embodiment, there is no limitation to this. For example, a connector to be attached to another device may also be adopted as the connection component. In this case, the case 12 is the case of the partner device to which the connector is to be attached.

Although the above embodiment and variation describe that when the compressive force that acts in the insertion direction with respect to the elastic members 40 and 60 does not occur, the elastic members 40 and 60 are not in contact with the case 12, a configuration may also be adopted in which the elastic members 40 and 60 come into slight contact with the case 12 on condition that the insertion force does not increase more than necessary.

The first thickness T1 and the second thickness T2 in the above embodiment may be respectively referred to as “maximum thickness before compression” and “maximum thickness after compression” of the elastic member 40 (or the annular portion 41). The dimension of the elastic member 40 in the insertion direction Z may also be referred to as “height of the elastic member 40 (or the annular portion 41)”. The height of the elastic member 40 (or annular portion 41) before compression may be referred to as “maximum height before compression”, and the height of the elastic member 40 (or the annular portion 41) after compression may be referred to as “maximum height after compression”. As shown in FIGS. 1 and 2, the maximum height after compression of the elastic member 40 (or annular portion 41) is smaller than the maximum height before compression thereof, and the maximum thickness after compression of the elastic member 40 (or annular portion 41) is greater than the maximum thickness before compression thereof.

The present disclosure includes the implementation examples as follows. Reference numerals of some constituent elements of the exemplary embodiment are given in order to facilitate understanding rather than limiting. Some of the items described in the following implementation examples may be omitted, and some of the items described in the implementation example may be selected or extracted to be combined with each other.

[Supplementary Note 1]

In some implementation examples of the present disclosure, when the compressive force that acts in the insertion direction (Z) to the case (12) does not occur, the elastic member (40) is the maximum thickness before compression (T1) on a surface (XY plane) orthogonal to the insertion direction (Z) and the maximum height before compression (see FIG. 2) in the insertion direction (Z),

when the compressive force that acts in the insertion direction (Z) to the case (12) occurs, the elastic member (40) is the maximum thickness after compression (T2) on the surface (XY plane) orthogonal to the insertion direction (Z) and the maximum height after compression (see FIG. 1) in the insertion direction (Z), and the maximum thickness after compression (T2) is larger than the maximum thickness before compression (T1), and the maximum height after compression is smaller than the maximum height before compression.

[Supplementary Note 2]

In some implementation examples of the present disclosure, the recessed portion (34A) of the main body portion (30) includes two stepped surfaces (34B, 34C) that are spaced apart from each other in the insertion direction (Z) and a radially outward surface that extends between the two stepped surfaces (34B, 34C), and when the compressive force does not act on the elastic member (40), the fitting protrusion (62) of the elastic member (40) is in contact with the radially outward surface of the recessed portion (34A), but not in contact with the two stepped surfaces (34B, 34C), and a space is formed between the two stepped surfaces (34B, 34C) and the fitting protrusion (62).

[Supplementary Note 3]

A connection component including a main body portion to be attached to a case, and an annular elastic member to which the main body portion is inserted,

wherein, when a compressive force that acts in the insertion direction into the case does not occur, the elastic member has a radial gap between an outer circumferential surface of the elastic member and an inner circumferential surface of the case, and

when the compressive force that acts in the insertion direction into the case occurs, the elastic member is compressed so as to fill the gap.

[Supplementary Note 4]

The connection component according to supplementary note 3,

wherein the compressive force deforms the elastic member in the direction intersecting the insertion direction.

[Supplementary Note 5]

The connection component according to supplementary note 3 or 4,

wherein one of the case and the connection component includes a guide pin, another of the case and the connection component includes an insertion hole for inserting the guide pin, and the case and the connection component are moved in the insertion direction and attached through the guide pin and the insertion hole.

1. A connection component comprising:
a main body to be attached to a case; and
an annular that is elastic and into which the main body is inserted,
wherein the annular ring deforms between a first thickness at which the annular ring is in contact with the main body and is not in contact with the case when a compressive force that acts in an insertion direction into the case does not occur, and a second thickness at which the annular ring is in contact with both the main body and the case when the compressive force that acts in the insertion direction into the case occurs.

2. The connection component according to claim 1,
wherein the annular ring includes an engagement that engages with the main body in the insertion direction.

3. The connection component according to claim 2, wherein:
the main body includes at least one of a recess and a protrusion, and
the engagement has a fitting shape that fits in the at least one of the recess and the protrusion provided in the main body.

4. The connection component according to claim 3, wherein:
the engagement is a fitting protrusion that fits in the recess of the main body, and
the fitting protrusion is provided at an intermediate position of the annular ring in the insertion direction.

5. The connection component according to claim 4,
wherein the fitting protrusion includes an abutment that abuts against the recess when the compressive force occurs on an upstream side in the insertion direction.

6. The connection component according to claim 4,
wherein the fitting protrusion includes a downstream side engagement configured to engage with the recess on a downstream side in the insertion direction.

7. The connection component according to claim 4,
wherein the fitting protrusion includes a chamfer that is formed in a curved shape at a corner of a base end.

8. The connection component according to claim 1,
wherein the annular ring includes an outer circumferential surface that bulges outwards.

9. The connection component according to claim 1,
wherein the annular ring includes a tapered lip at both ends on the upstream and downstream sides in the insertion direction.

10. A connection unit comprising:
a case; and
a connection component including a main body that is attached to the case and an annular ring that is elastic and into which the main body is inserted,
wherein the annular ring deforms between a first thickness at which the annular ring elastic member is in contact with the main body and is not in contact with the case when a compressive force that acts in an insertion direction into the case does not occur, and a second thickness at which the annular ring is in contact with both the main body and the case when the compressive force that acts in the insertion direction into the case occurs.

11. The connection unit according to claim 10,
wherein the case includes a housing that houses the annular ring and is in contact with the annular ring in a direction that intersects the insertion direction when the annular ring is the second thickness.

12. The connection unit according to claim 10,
wherein one of the case and the connection component includes a guide pin, and the other of the case and the connection component includes an insertion hole for inserting the guide pin.

13. The connection unit according to claim 10,
wherein the main body includes a lid that closes an opening of the case and an insertion body to be inserted into the opening.

14. The connection unit according to claim 13,
wherein a leading end of the insertion body has a tapered shape that is tapered toward a leading end side.

15. The connection unit according to claim 10, comprising:
a holding body that holds the annular ring of the connection component in the case in a state where the annular ring is the second thickness.

16. The connection unit according to claim 15,
wherein the holding body is a thread fastening member.
